(19) United States
(12) Patent Application Publication
(10) Pub. No.: US 2012/0077307 A1
(43) Pub. Date: Mar. 29, 2012

(54) ETCHING PASTE HAVING A DOPING FUNCTION AND METHOD OF FORMING A SELECTIVE EMITTER OF A SOLAR CELL USING THE SAME

(76) Inventors: Dong Jun KIM, Uiwang-si (KR); Kuninori Okamoto, Uiwang-si (KR); Byung Chul Lee, Uiwang-si (KR); Seok Hyun Jung, Uiwang-si (KR)

(21) Appl. No.: 13/313,306

(22) Filed: Dec. 7, 2011

Related U.S. Application Data
(63) Continuation of application No. PCT/KR2009/007138, filed on Dec. 2, 2009.

(30) Foreign Application Priority Data
Jun. 8, 2009 (KR) 10-2009-0050463

(51) Int. Cl. H01L 31/18; C09K 13/00

(52) U.S. Cl. 438/98; 252/79.1; 257/E31.124

(57) ABSTRACT

An etching paste having a doping function for etching a thin film on a silicon wafer and a method of forming a selective emitter of a solar cell, the etching paste including an n-type or p-type dopant; a binder; and a solvent.

### CROSS-REFERENCE TO RELATED APPLICATION

This application is a continuation of pending International Application No. PCT/KR2009/007138, entitled “Etching Paste Having Doping Function, and Formation Method of Selective Emitter of Solar Cell Using the Same,” which was filed on Dec. 2, 2009, the entire contents of which are hereby incorporated by reference.

### BACKGROUND

1. Field

Embodiments relate to an etching paste having a doping function and a method of forming a selective emitter of a solar cell using the same.

2. Description of the Related Art

A process of manufacturing a silicon crystal solar cell may include diffusing impurities into a light-receiving surface of a silicon crystalline wafer, in which the impurities have a conductivity type opposite to the conductivity type of the silicon substrate. After forming a p-n junction through diffusion of the impurities, electrodes may be formed on the light receiving surface and a rear surface of the silicon substrate, respectively, thereby providing a solar cell.

In order to enhance power generation efficiency of a silicon crystal solar cell, a surface area of the light receiving surface may be increased through a texturing treatment (using an alkali solution, e.g., KOH, to increase an amount of radiation on the light receiving surface) and/or forming an anti-reflection layer thereon to prevent reflection of sunlight.

In addition, impurities having the same conductivity type as that of the silicon substrate may be diffused in a high density on the rear surface of the silicon substrate to induce high output through electrolytic effects on the rear surface.

### SUMMARY

Embodiments are directed to an etching paste having a doping function and a method of forming a selective emitter of a solar cell using the same.

The embodiments may be realized by providing an etching paste having a doping function for etching a thin film on a silicon wafer, the etching paste comprising an n-type or p-type dopant; a binder; and a solvent.

The thin film may include a silicon oxide film, a silicon nitride film, a metal oxide film, or a non-crystalline silicon film.

The paste may include about 0.1 to about 98 wt % of the dopant; about 0.1 to about 10 wt % of the binder; and about 1.9 to about 99.8 wt % of the solvent.

The dopant may include at least one selected from lanthanum boride (LaB₆) powder, aluminum (Al) powder, metal bismuth (Bi) powder, and bismuth oxide (Bi₂O₃) powder.

The binder may include an organic binder, an inorganic binder, or a mixture thereof.

The binder may include the organic binder, the organic binder including at least one selected from the group of cellulose resins, (meth)acrylic resins, and polyvinyl acetal resins.

The binder may include the inorganic binder, the inorganic binder including glass frit including at least one component selected from the group of lead oxide, bismuth oxide, silicon oxide, zinc oxide, and aluminum oxide.

The etching paste may be substantially free from a fluorine or phosphorus compound.

The embodiments may also be realized by providing a method of forming a selective emitter of a solar cell, the method including depositing the etching paste according to an embodiment on a silicon wafer having a thin film formed thereon; and firing the silicon wafer with the etching paste deposited thereon to simultaneously etch the thin film and dope the dopant into the silicon wafer to form a doping region.

The silicon wafer may not be subjected to pretreatment of texturing or doping.

The firing may be performed at about 800 to about 1,000° C. for about 5 to about 120 minutes.

The method may further include depositing an electrode paste on the doping region to form an electrode.

The thin film may include a silicon oxide film, a silicon nitride film, a metal oxide film, or a non-crystalline silicon film.

The etching paste may include about 0.1 to about 98 wt % of the dopant; about 0.1 to about 10 wt % of the binder; and about 1.9 to about 99.8 wt % of the solvent.

The dopant may include at least one selected from lanthanum boride (LaB₆) powder, aluminum (Al) powder, metal bismuth (Bi) powder, and bismuth oxide (Bi₂O₃) powder.

The binder may include an organic binder, an inorganic binder, or a mixture thereof.

The binder may include the organic binder, the organic binder including at least one selected from the group of cellulose resins, (meth)acrylic resins, and polyvinyl acetal resins.

The binder may include the inorganic binder, the inorganic binder including glass fit including at least one component selected from the group of lead oxide, bismuth oxide, silicon oxide, zinc oxide, and aluminum oxide.

The etching paste may be substantially free from a fluorine or phosphorus compound.

### BRIEF DESCRIPTION OF THE DRAWINGS

The above and other features and advantages will become more apparent to those of ordinary skill in the art by describing in detail exemplary embodiments with reference to the attached drawings, in which:

FIGS. 1(a) to 1(d) illustrate diagrams of stages in a method of forming a selective emitter of a solar cell using a paste according to an embodiment.

### DETAILED DESCRIPTION

Korean Patent Application No. 10-2009-0050463, filed on Jun. 8, 2009, in the Korean Intellectual Property Office, and entitled: “Etching Paste Having Doping Function, and Formation Method of Selective Emitter of Solar Cell Using the Same,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

An etching paste according to an embodiment may facilitate simultaneous doping and etching. As used herein, the term ‘simultaneously’ or ‘at the same time’ may refer to etching and doping being performed using a single paste in view of a process, instead of referring to concurrence in terms of time.

For example, an embodiment provides a paste, e.g., an etching paste used for etching a thin film on a silicon wafer. The paste may include: a) an n-type or p-type dopant; b) a binder; and c) a solvent.

The thin film may include, e.g., a silicon oxide film, a silicon nitride film, a metal oxide film, or a non-crystalline silicon film.

The dopant may include at least one of lanthanum boride (LaB₆) based powder, aluminum (Al) powder, metal bismuth (Bi) powder, and bismuth oxide (Bi₂O₃) powder. In order to form a p-type doping region, the dopant may include a group-III element, e.g., B, Al, and the like. In order to form an n-type doping region, the dopant may include a group-V element, e.g., Bi and the like.

The dopant may be present in the paste in an amount of about 0.1 to about 98 wt %, e.g., about 10 to about 85 wt % or about 40 to about 80 wt %. Maintaining the amount of the dopant at about 0.1 wt % or greater may help ensure that sufficient doping and etching effects are obtained. Maintaining the amount of the dopant at about 98 wt % or less may help ensure that the paste has sufficient fluidity, thereby facilitating selective printing.

The binder may include an organic binder, an inorganic binder, or a mixture thereof.

The organic binder may include, e.g., cellulose resins, (meth)acrylic resins, and/or polyvinylacetal resins. These organic binders may be used alone or in combination of two or more thereof.

In an implementation, the organic binder may include the cellulose resin, e.g., ethyl cellulose, nitrocellulose, and the like.

The inorganic binder may include glass frit. The glass frit may include at least one component selected from the group of lead oxide, bismuth oxide, silicon oxide, zinc oxide, and aluminum oxide, without being limited thereto.

The inorganic binder may be used alone or in combination of two or more thereof. When a powdery inorganic binder is used, the powdery inorganic binder may be dispersed in a solvent to achieve an appropriate viscosity.

The binder may be present in the paste in an amount of about 0.1 to about 10 wt %. Maintaining the amount of the binder at about 0.1 wt % or greater may help ensure that proper printability and sufficient adhesion of the paste are obtained. Maintaining the amount of the binder at about 10 wt % or less may help ensure that large amounts of residues, e.g., coal, do not remain, thereby avoiding unsatisfactory resistance. In an implementation, the binder may be present in an amount of about 1 to about 10 wt %, e.g., about 3 to about 10 wt %.

The solvent may include an organic solvent, e.g., methyl cellosolve, ethyl cellosolve, butyl cellosolve, aliphatic alcohols, α-terpineol, β-terpineol, dihydro-terpineol, ethylene glycol, ethylene glycol mono butyl ether, butyl cellosolve acetate, and/or Texanol. In an implementation, the solvent may include, e.g., butyl carbitol acetate. The solvent may be used alone or in combination of two or more thereof.

The solvent may be present as a balance weight in the paste, e.g., except for the dopant and the binder. In an implementation, the solvent may be present in an amount of about 1.9 to about 99.8 wt %, e.g., about 5 to about 80 wt % or about 20 to about 70 wt %.

The paste may further include an additive, e.g., viscosity stabilizers, anti-foaming agents, thixotropic agents, dispersing agents, leveling agents, antioxidants, thermal polymerization inhibitors, and the like. The additive may be used alone or in combination of two or more thereof.

The paste according to the embodiments may be substantially free from a fluorine or phosphorus compound (which may cause problems in terms of corrosiveness, toxicity, and the like). Thus, the paste may be environmentally friendly and may not require a washing process, even after doping and etching.

Another embodiment provides a method of forming a selective emitter of a solar cell using the etching paste.

The etching paste according to an embodiment may facilitate simultaneous etching of a thin film on a surface of a silicon wafer and doping of the silicon wafer through a firing process.

The method may use an etching paste including a) an n-type or p-type dopant, b) a binder, and c) a solvent, and may include depositing the etching paste on a silicon wafer having a thin film formed thereon; and firing the silicon wafer with the etching paste deposited thereon to allow etching of the thin film and doping of the dopant into the silicon wafer to form a doping region to be simultaneously performed.

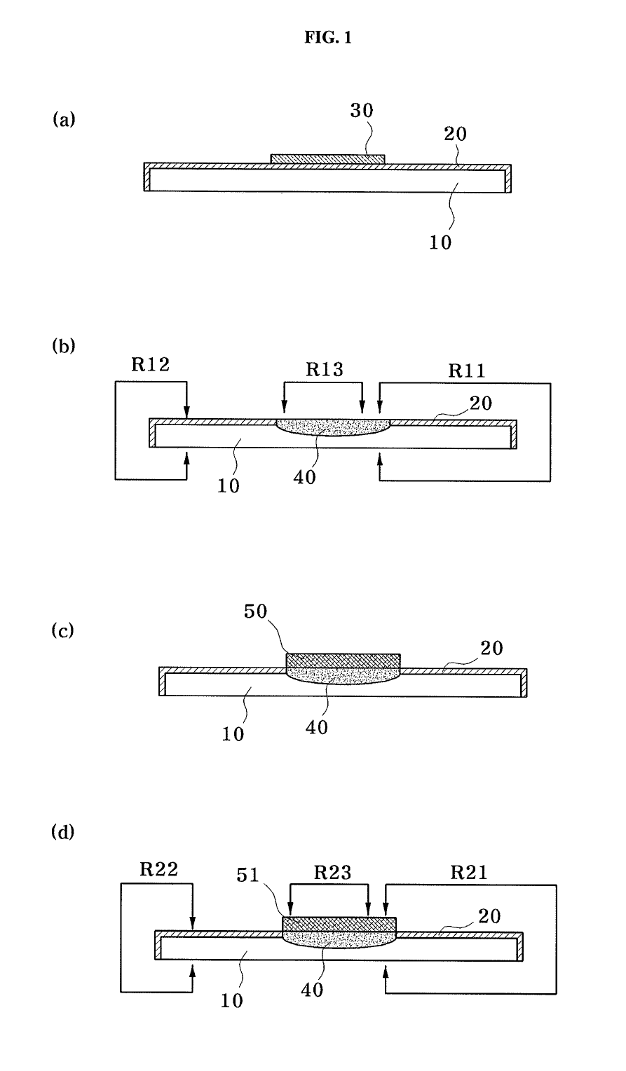

FIGS. 1(a) to 1(d) illustrate diagrams showing stages in the method of forming a selective emitter of a solar cell using a paste according to an embodiment.

As shown in FIG. 1(a), an etching paste 30 according to an embodiment may be deposited on a silicon wafer 10 having a thin film 20 formed thereon. The etching paste 30 may be deposited on the silicon wafer 10 by, e.g., screen printing, offset-printing, and the like. The etching paste 30 may be a nontoxic etching paste

Part of the silicon wafer 10 to be deposited with the etching paste 30 may correspond to a region on which the thin film 20 will be subjected to etching such that the dopant is doped therethrough. Further, the part of the silicon wafer 10 to be deposited with the etching paste 30 may also correspond to a region on which electrodes will be formed by depositing an electrode paste 50 described below (see FIG. 1(c)).

In an implementation, the etching paste 30 may be deposited to a thickness of about 0.1 to about 15 μm, e.g., about 3 to about 10 μm.

The silicon wafer 10 may include a single crystal, polycrystalline, or non-crystalline silicon semiconductor substrate. The silicon wafer 10 may have any suitable size and shape. The silicon wafer 10 may be a p-type substrate as used in general crystalline silicon solar cells. Alternatively, an n-type substrate may be used as the silicon wafer 10. Further, a silicon wafer not subjected to texturing or doping may be used as the silicon wafer.

Examples of the thin film 20 may include silicon oxide films, silicon nitride films, metal oxide films, non-crystalline silicon films, and other natural oxide films, without being limited thereto. The thin film 20 may be formed by, e.g., vacuum deposition, chemical vapor deposition, sputtering, electron beam deposition, spin coating, screen printing, spray coating, or the like.

For example, in application of the embodiments to a solar cell, the thin film 20 may serve as an anti-reflection film. The anti-reflection film may reduce reflection of sunlight from a front surface of the silicon wafer 10 (or substrate).

As shown in FIG. 1(b), a doping region 40 may be formed on the silicon wafer 10 simultaneously with etching of the thin film 20 through a firing process.

The dopant of the etching paste 30 according to the embodiment may infiltrate into the thin film 20 and may form a doped region on the silicon wafer 10, e.g., the doping region 40. In order to form a p-type doping region 40, the dopant may include a group-III element, e.g., B, Al, or the like. In order to form an n-type doping region 40, the dopant may include a group-V element, e.g., Bi or the like. When the n-type doping region 40 is formed on a p-type silicon wafer 10, a p-n junction may be formed at an interface therebetween, and when the p-type doping region 40 is formed on an n-type silicon wafer 10, the p-n junction may be formed at an interface therebetween.

As used herein, the term “etching” has a slightly different meaning than the general meaning of etching. Some dopant of the etching paste 30 infiltrates into the thin film 20 and forms a doping region 40 in a predetermined area of the silicon wafer 10, in which the thin film 20 serves as a protective layer. Further, the etching paste 30 replaces the thin film 20 while forming the doping region 40. In view of this point, the term “etching” as used herein has a similar meaning to the meaning of general etching, by which the thin film is removed.

Firing may be performed at about 800 to about 1,000° C. for about 5 to about 120 minutes. Maintaining the firing temperature at about 800° C. or higher and the firing time at about 5 minutes or greater may help ensure that the desired doping region 40 is formed. Maintaining the firing temperature at about 1,000° C. or lower and the firing time at about 120 minutes or less may help prevent the doping region 40 from being formed too deep, thereby facilitating formation of a desired p-n junction.

As shown in FIG. 1(c) a process of depositing and drying an electrode paste 50 for forming an electrode on an etched region may be performed.

An electrode paste may include a curing-type and/or a firing-type. The embodiments may be applied to both the curing-type and the firing-type. In an implementation, the curing-type electrode paste may be used.

In an implementation, the electrode paste may include a conductive powder, glass fit, organic vehicles, and the like. For example, silver powder may be used as the conductive powder.

In an implementation, the electrode paste 50 may be deposited by screen printing. The electrode paste 50 may be dried after being deposited.

As shown in FIG. 1(d) a process of forming an electrode 51 by curing or sintering the dried electrode paste 50 may be performed.

When the curing type electrode paste is used, the electrode paste may be cured at about 150 to about 250° C. for about 10 to about 60 minutes.

When the firing type electrode paste is used, the paste may be subjected to firing at about 700 to about 1,000° C. for about 1 to about 60 minutes in a furnace. The furnace may include, e.g., an IR furnace.

In an implementation, the electrode may have a thickness of about 10 to about 40 μm, e.g., about 15 to about 30 μm.

The solar cell manufactured by the method as described above may have a resistance of about 1 to about 320Ω between the electrode and the silicon substrate on the rear surface thereof. In an implementation the resistance may be about 1 to about 200Ω, e.g., about 1 to about 100Ω or about 1 to about 50Ω.

The following Examples and Comparative Examples are provided in order to set forth particular details of one or more embodiments. However, it will be understood that the embodiments are not limited to the particular details described. Further, the Comparative Examples are set forth to highlight certain characteristics of certain embodiments, and are not to be construed as either limiting the scope of the invention as exemplified in the Examples or as necessarily being outside the scope of the invention in every respect.

### Example 1a

A 5 inch, 250 μm thick p-type silicon substrate not subjected to texturing or doping was prepared. On the substrate, an etching paste (prepared by dispersing 50 parts by weight of lanthanum boride powder (LaB₆, Aldrich Co., Ltd), 5 parts by weight of a binder (Etocel, Dow Corning Company), 15 parts by weight of butyl carbitol acetate, and 30 parts by weight of terpineol using a roll mill) was deposited onto a 2×3 cm² ribbon via screen printing. The etching paste was deposited to a thickness of 5 to 7 μm. Then, the specimen was dried at 150° C. for 20 minutes in an oven. The dried specimen was subjected to firing in a furnace set to have a peak temperature of 850° C. for 7 minutes, 9 minutes, 15 minutes, and 34 minutes through adjustment of belt speed.

An electrode paste was deposited on the fired specimen. The electrode paste was prepared by mixing 80 parts by weight of spherical Ag powder (Dowa Holdings Co., Ltd.) with 20 parts by weight of a vehicle prepared by dissolving an epoxy-based binder (YDCN-7P, Kukdo Chemicals Co., Ltd.) in butyl carbitol acetate, followed by dispersing the mixture using a roll mill. Then, the paste was subjected to drying and firing at 200° C. for 30 minutes to form an electrode. The electrode had a thickness of 20 μm. Surface resistance (unit: Ω) between the Ag electrode on the surface of the cell and the silicon substrate on the rear surface thereof was measured using a two-terminal probe. The results are shown in Table 1, below.

### Example 1b

Example 1b was carried out in the same manner as in Example 1a except that aluminum powder (Al, High Purity Chemistry Research Center) was used instead of the lanthanum boride powder.

### Example 1c

Example 1c was carried out in the same manner as in Example 1a except that metal bismuth powder (Bi, High Purity Chemistry Research Center) was used instead of the lanthanum boride powder.

### Example 1d

Example 1d was carried out in the same manner as in Example 1a except that bismuth oxide powder (Bi₂O₃, High Purity Chemistry Research Center) was used instead of the lanthanum boride powder.

### Comparative Example 1a

Comparative Example 1a was carried out in the same manner as in Example 1a except that silver powder (Ag, Dowa Holdings Co., Ltd.) was used instead of the lanthanum boride powder.

### Comparative Example 1b

Comparative Example 1b was carried out in the same manner as in Example 1a except that antimony oxide powder (Sb₂O₃, Aldrich Co., Ltd.) was used instead of the lanthanum boride powder.

### Comparative Example 1c

Comparative Example 1c was carried out in the same manner as in Example 1a except that silver powder (Ag, Dowa Holdings Co., Ltd.) was used instead of the lanthanum boride powder, and a washing process using HF was additionally performed after screen printing the etching paste.

TABLE 1

| | | | Firing condition (peak | | | |
|---|---|---|---|---|---|---|
| | | Test | temperature: 850° C.) | | | |
| | Dopant | Number | 34 min | 15 min | 9 min | 7 min |
| Example 1a | LaB₆ | #1 | 36 | 58 | 100 | 300 |
| | | #2 | 61 | 80 | 120 | 320 |
| | | #3 | 32 | 62 | 130 | 310 |
| | | Average | 43 | 67 | 117 | 310 |
| Example 1b | Al | #1 | 63 | 110 | 170 | 300 |
| | | #2 | 67 | 124 | 160 | 290 |
| | | #3 | 65 | 120 | 192 | 300 |
| | | Average | 65 | 118 | 174 | 287 |
| Example 1c | Bi | #1 | 100 | 160 | 180 | 250 |
| | | #2 | 120 | 160 | 230 | 230 |
| | | #3 | 100 | 200 | 180 | 320 |
| | | Average | 107 | 173 | 197 | 267 |
| Example 1d | Bi₂O₃ | #1 | 59 | 125 | 220 | 300 |
| | | #2 | 52 | 118 | 280 | 290 |
| | | #3 | 60 | 129 | 260 | 310 |
| | | Average | 57 | 124 | 253 | 300 |
| Comparative | Ag | #1 | 310 | 260 | 270 | 300 |
| Example 1a | | #2 | 270 | 260 | 250 | 290 |
| | | #3 | 230 | 254 | 260 | 295 |
| | | Average | 270 | 258 | 260 | 295 |
| Comparative | Sb₂O₃ | #1 | 280 | 255 | 190 | 280 |
| Example 1b | | #2 | 270 | 250 | 150 | 270 |
| | | #3 | 280 | 245 | 110 | 250 |
| | | Average | 277 | 250 | 150 | 267 |
| Comparative | Ag | #1 | 325 | 330 | 365 | 410 |
| Example 1c | | #2 | 320 | 346 | 340 | 400 |
| | | #3 | 340 | 350 | 370 | 405 |
| | | Average | 328 | 342 | 358 | 405 |

As may be seen in Table 1, Examples 1a to 1d exhibited lower surface resistance than Comparative Examples 1a to 1b. This result was especially apparent when the firing time exceeded 30 minutes. Further, when compared with the cell prepared through the washing process as in Comparative Example 1c, it may be seen that Examples 1a to 1d exhibited low surface resistance.

Therefore, it may be seen that the paste according to the embodiments is a screen printable doping paste that is free from a fluorine or phosphorus compound having high toxicity and corrosiveness, and may not require a washing process.

### Example 2

### Example 2a

A 0.8 mm thick silicon substrate having a 1,600 Å thick silicon nitride layer formed thereon by normal pressure CVD was cut to a size of 3 cm×10 cm, thereby preparing a specimen. On the specimen, an etching paste (prepared by dispersing 50 parts by weight of lanthanum boride powder (LaB₆, Aldrich Co., Ltd), 5 parts by weight of a binder (Etocel, Dow Corning Company), 15 parts by weight of butyl carbitol acetate, and 30 parts by weight of terpineol using a roll mill) was deposited onto a 2×5 cm² ribbon via screen printing. The etching paste was deposited to a thickness of 3 to 10 μm. Then, a specimen was dried at 150° C. for 20 minutes in an oven. The dried specimen was subjected to firing in a furnace set to have a peak temperature of 850° C. for 30 minutes. To confirm etching effects, the fired specimen was dipped into a 50 wt % HF solution, followed by removal of surface by-products. Then, surface resistance was measured using a two-terminal probe. The results are shown in Table 2, below.

An electrode paste was deposited on the doped region of the silicone substrate of the specimen without washing the fired specimen. The electrode paste was prepared by mixing 80 parts by weight of spherical Ag powder (Dowa Holdings Co., Ltd.) with 20 parts by weight of a vehicle prepared by dissolving an epoxy-based binder (YDCN-7P, Kukdo Chemicals Co., Ltd.) in butyl carbitol acetate, followed by dispersing the mixture using a roll mill. Then, the paste was subjected to drying and firing at 200° C. for 30 minutes to form an electrode. The electrode had a thickness of 20 μm. Surface resistance (unit: Ω) between the Ag electrode on the surface and the silicon substrate on the rear surface was measured using a two-terminal probe. Results are shown in Table 2, below. In Table 2, “∘” indicates that conductivity was observed, and “X” indicates that conductivity was not observed.

### Example 2b

Example 2b was carried out in the same manner as in Example 2a except that aluminum powder (Al, High Purity Chemistry Research Center) was used instead of the lanthanum boride powder.

### Example 2c

Example 2c was carried out in the same manner as in Example 2a except that metal bismuth powder (Bi, High Purity Chemistry Research Center) was used instead of the lanthanum boride powder.

### Example 2d

Example 2d was carried out in the same manner as in Example 2a except that bismuth oxide powder (Bi₂O₃, High Purity Chemistry Research Center) was used instead of the lanthanum boride powder.

### Comparative Example 2a

Comparative Example 2a was carried out in the same manner as in Example 2a except that silver powder (Ag, Dowa Holdings Co., Ltd.) was used instead of the lanthanum boride powder.

### Comparative Example 2b

Comparative Example 2b was carried out in the same manner as in Example 2a except that antimony oxide powder (Sb₂O₃, Aldrich Co., Ltd.) was used instead of the lanthanum boride powder.

TABLE 2

| | | Surface | | Electrical |
|---|---|---|---|---|
| | Etchant | resistance | | conduction |
| Example 2a | LaB₆ | 150 | Ω | ◯ |
| Example 2b | Al | 18 | Ω | ◯ |
| Example 2c | Bi | 60 | Ω | ◯ |
| Example 2d | Bi₂O₃ | 90 | Ω | ◯ |
| Comparative Example | Ag | ∞ | | X |
| 2a | | | | |
| Comparative Example | Sb₂O₃ | 2.0 × 10⁸ | Ω | X |
| 2b | | | | |

| | | | |
|---|---|---|---|
| Reference | Si-wafer | ∞ | X |

As may be seen in Table 2, Examples 2a to 2d had a surface resistance of 200Ω or less. On the other hand, Comparative Example 2a had the same results as those of a pure silicon wafer provided as a reference. Further, Comparative Example 2b had high resistance after washing. Thus, it may be seen that Examples 2a to 2d had etching and doping effects. Therefore, it may be seen that the paste according to the embodiments is a screen printable doping paste that is capable of etching a silicon oxide or silicon nitride layer without using a fluorine or phosphorus compound having high toxicity and corrosiveness, and may not require a washing process.

### Example 3

### Example 3a

A 0.8 mm thick silicon substrate having a 1,600 Å thick silicon nitride layer formed by normal pressure CVD was cut to a size of 3 cm×10 cm, thereby preparing a specimen. On the specimen, an etching paste prepared by dispersing 50 parts by weight of lanthanum boride powder (LaB₆, Aldrich Co., Ltd), 5 parts by weight of a binder (Etocel, Dow Corning Company), 15 parts by weight of butyl carbitol acetate, and 30 parts by weight of terpineol using a roll mill was deposited onto a 2×5 cm² ribbon via screen printing. The etching paste was deposited to a thickness of 6 μm. Then, the specimen was dried at 150° C. for 20 minutes in an oven. The dried specimen was subjected to firing in a furnace set to have a peak temperature of 850° C. for 30 minutes. Electrical conduction at R11, R12, and R13 (see FIG. 1(b)) was measured using a two-terminal probe without removal of surface by-products. Results are shown in Table 3, below. In Table 3, “∘” indicates that conductivity was observed, and “X” indicates that conductivity was not observed.

A firing-type Ag paste was deposited on the silicon nitride layer of the specimen without washing the fired specimen. The firing-type Ag paste was prepared by mixing 80 wt % of spherical Ag powder (Dowa Holdings Co., Ltd.), 4 wt % of glass fit (Particlogy Co., Ltd.), 1.6 wt % Ethocel ethylcellulose (Dow Industries Co., Ltd.), and 14.4 wt % of a solvent obtained by blending BCA and terpineol in a ratio of 3:7, followed by dispersing the mixture using a 3-roll mill. Then, the paste was subjected to drying and firing at 850° C. for 2 minutes in an IR furnace to form an electrode. The electrode had a thickness of 12 μm. In addition to resistance at R21 between the Ag electrode on the surface and the silicon substrate on the rear surface, resistance at R21, R22, and R23 (see FIG. 1(d)) was measured using a two-terminal probe. Results are shown in Table 4, below.

### Example 3b

Example 3b was carried out in the same manner as in Example 3a except that bismuth oxide powder (Bi₂O₃, High Purity Chemistry Research Center) was used instead of the lanthanum boride powder.

### Example 3c

Example 3c was carried out in the same manner as in Example 3a except that metal bismuth powder (Bi, High Purity Chemistry Research Center) was used instead of the lanthanum boride powder.

### Example 3d

Example 3c was carried out in the same manner as in Example 3a except that 25 parts by weight of lanthanum boride powder and 25 parts by weight of bismuth oxide powder (Bi₂O₃, High Purity Chemistry Research Center) was used instead of 50 parts by weight of lanthanum boride powder.

### Example 3e

Example 3e was carried out in the same manner as in Example 3a except that aluminum powder (Al, High Purity Chemistry Research Center) was used instead of the lanthanum boride powder.

TABLE 3

| | Etching & | | | |
|---|---|---|---|---|
| | Dopant | R11 | R12 | R13 |
| Example 3a | LaB₆ | X | X | X |
| Example 3b | Bi₂O₃ | X | X | X |
| Example 3c | Bi | X | X | X |
| Example 3d | LaB₆ + Bi₂O₃ | X | X | X |
| Example 3e | Al | ◯ | X | ◯ |

As may be seen in Table 3, when the wafer was subjected to etching and doping before formation of the electrode, electrical conduction did not occur. Exceptionally, it may be seen that electrical conduction occurred at R11 and R13 due to the Al powder contained in the paste according to Example 3e.

TABLE 4

| | Dopant | R21 | | R22 | R23 |
|---|---|---|---|---|---|
| Example 3a | LaB₆ | 2.8 | kΩ | ∞ | 0.2 Ω/sq |
| Example 3b | Bi₂O₃ | 9 | kΩ | ∞ | 0.2 Ω/sq |
| Example 3c | Bi | 16.8 | kΩ | ∞ | 0.2 Ω/sq |
| Example 3d | LaB₆ + Bi₂O₃ | 5 | kΩ | ∞ | 0.2 Ω/sq |
| Example 3e | Al | 6 | kΩ | ∞ | 0.2 Ω/sq |

As may be seen in Table 4, when the electrode was formed of the firing-type Ag paste, without removal of surface by-products through washing, after the wafer was subjected to etching and doping by the paste according to the embodiments, electrical conduction occurred through the Ag electrode. Thus, it may be seen that the thin film under the Ag electrode was etched and had a doping region therein.

The paste according to the embodiments may be free from a fluorine compound or a phosphorus compound. Thus, the paste may avoid problems of high corrosiveness and toxicity and may eliminate a washing process even after doping and etching. Further, the paste according to the embodiments may allow doping and etching to be performed simultaneously, thereby improving process efficiency while achieving cost reduction through integration of two processes into a single process.

By way of summation and review, various methods for achieving improvement of power generation efficiency have been considered.

For example, power generation efficiency of a solar cell may be improved through formation of a certain structure, e.g., a shallow emitter, a selective emitter, or the like.

Specifically, when the silicon substrate is a p-type substrate, an n-type impurity-diffused layer may be formed as thin as possible on a light receiving surface of the silicon substrate to thereby increase an amount of photoelectrons reaching the p-n junction. Here, sunlight may be shielded to compensate for an increase in surface resistance, and an n-type impurity-diffused layer may be selectively formed deep under an electrode that does not participate in light-receiving efficiency.

As a method of forming a selective emitter structure, use of paste prepared by mixing impurities containing a phosphorous (P) compound has been considered. One method using such a paste may include (1) texturing a substrate surface through alkali treatment as in a Cz-Si solar cell, (2) printing the substrate with the paste containing phosphorus to form a pattern on the surface of the substrate, followed by drying, (3) selective diffusion at about 960° C. through doping, (4) selective thermal oxidation at about 800° C., (5) PECVD SiNx:H (direct plasma) deposition, and (6) and formation of a front Ag electrode through screen printing.

Another method using such a paste is a process of forming a polycrystalline selective emitter solar cell, and may include (1) isotropically texturing a substrate using an acid, (2) printing the substrate with the paste containing phosphorus to form a pattern on the surface of the substrate, followed by drying, (3) selective diffusion at about 850° C. through doping, (4) plasma etching of a parasitic junction, (5) PECVD SiNx:H (direct plasma) deposition, (6) formation of a front Ag electrode through screen printing, (7) formation of a rear Ag electrode through screen printing, and (8) firing both electrodes formed as described above.

A doping paste may include, as a doping component, at least one selected from boron salts, boron oxide, boric acid, organic boron compounds, boron aluminum compounds, phosphorus salts, phosphorus oxide, phosphoric acid, organic phosphorus compounds, organic aluminum compounds, aluminum salts, and the like, in a SiO₂ matrix.

Use of the doping paste employing SiO₂ as a matrix may result in formation of phosphorus (P) or borosilicate glass/oxide glass during a heating/diffusing process for doping, thereby causing a significant reduction of adhesion with respect to an electrode formed thereon or causing separation of the electrode therefrom. Thus, it may be necessary to perform a washing process using HF or the like in order to remove the phosphorus (P) or borosilicate glass/oxide glass.

In another method, impurities may be mixed with an electrode paste and diffused into a wafer during firing of an electrode, such that the density of impurities may be higher under the electrode than any other regions. Further, the paste mixed with the impurities may be applied to a region (on which an electrode will be formed) such that a diffusing layer may be selectively formed.

However, in the method of mixing the impurities with the electrode paste to be diffused into the wafer during firing the electrode, the electrode may increase in electrical resistance with increasing density of impurities in the electrode paste, thereby deteriorating cell properties, e.g., a fill factor.

If the density of impurities is low, the process of firing the electrode may be performed after the diffusing process and may be carried out at a lower temperature than the diffusing process, thereby making it very difficult to obtain effects of the selective emitter.

Further, when the paste mixed with the impurities is deposited through screen printing, it may be difficult to form a thin film to a thickness of dozens of nanometers or less, and organic materials used as media may remain on the wafer surface, thereby adversely influencing properties of the solar cell.

Accordingly, the selective emitter structure may be formed by partially etching a silicon oxide or silicon nitride layer on the silicon substrate so as to correspond to an electrode pattern, and diffusing impurities through the removed portion of the silicon oxide or silicon nitride layer. Thus, a separate etching paste may be used to remove the silicon oxide or silicon nitride layer from the substrate surface.

In the firing process for formation of electrodes independent of the process of forming the selective emitter structure, a polymer-based metal paste may be used to prevent defects of a silicon crystal or contamination caused by impurities. In this case, the polymer-based metal paste may typically be cured at about 200° C. Thus, it may be necessary to remove the silicon oxide or silicon nitride layer from the silicon substrate so as to correspond to the electrode pattern. Therefore, the etching paste is inevitably used.

The etching paste used for this purpose may include a fluorine compound, e.g., an ammonium-fluoride compound, as an etching component. However, since high reactivity and corrosiveness of the fluorine compound may require that great care be used, industrial use of the fluorine compound may be restricted and washing may inevitably be performed after etching.

Although a phosphorus compound, e.g., phosphoric acid, phosphate, or other compounds, may be used instead of the fluorine compound, use of the phosphorus compound may also be restricted due to high corrosiveness and moisture absorption characteristics, and washing may also be required after etching.

Moreover, the compositions of the doping paste may be different from those of the etching paste. Thus, the doping process may be performed separately from etching, thereby significantly deteriorating process efficiency.

The embodiments provide an etching paste capable of etching and doping a silicon wafer having a thin film formed thereon.

The embodiments also provide an etching paste having a doping function, which facilitates simultaneous performance of doping and etching, thereby improving process efficiency.

The embodiments also provide an environmentally friendly etching paste having a doping function, which is free from a fluorine compound or a phosphorus compound having high corrosiveness and toxicity due to high chemical reactivity.

The embodiments also provide an etching paste having a doping function, which may eliminate a washing process even after doping and etching.

The embodiments also provide an etching paste having a doping function, which may minimize resistance between an electrode and a silicon substrate.

The embodiments also provide a method of forming a selective emitter of a solar cell, which may include simultaneously performing doping and etching using the etching paste having a doping function.

The embodiments also provide a method of forming a selective emitter of a solar cell, which may eliminate a washing process even after doping and etching.

According to the embodiments, a nontoxic paste may be used instead of a fluorine compound or a phosphorus compound, thereby avoiding problems of high corrosiveness and toxicity due to high chemical reactivity.

In addition, the paste according to the embodiments may be nontoxic. Thus, a washing process may not be needed even after doping and etching.

Further, the paste according to the embodiments allows doping and etching to be performed simultaneously, thereby improving process efficiency while achieving cost reduction through integration of two processes into a single process.

Example embodiments have been disclosed herein, and although specific terms are employed, they are used and are to be interpreted in a generic and descriptive sense only and not for purpose of limitation. Accordingly, it will be understood by those of skill in the art that various changes in form and details may be made without departing from the spirit and scope of the present invention as set forth in the following claims.

What is claimed is:

1. An etching paste having a doping function for etching a thin film on a silicon wafer, the etching paste comprising:
an n-type or p-type dopant;
a binder; and
a solvent.

2. The etching paste as claimed in claim 1, wherein the thin film includes a silicon oxide film, a silicon nitride film, a metal oxide film, or a non-crystalline silicon film.

3. The etching paste as claimed in claim 1, wherein the etching paste includes:
about 0.1 to about 98 wt % of the dopant;
about 0.1 to about 10 wt % of the binder; and
about 1.9 to about 99.8 wt % of the solvent.

4. The etching paste as claimed in claim 1, wherein the dopant includes at least one selected from lanthanum boride (LaB₆) powder, aluminum (Al) powder, metal bismuth (Bi) powder, and bismuth oxide (Bi₂O₃) powder.

5. The etching paste as claimed in claim 1, wherein the binder includes an organic binder, an inorganic binder, or a mixture thereof.

6. The etching paste as claimed in claim 5, wherein the binder includes the organic binder, the organic binder including at least one selected from the group of cellulose resins, (meth)acrylic resins, and polyvinyl acetal resins.

7. The etching paste as claimed in claim 5, wherein the binder includes the inorganic binder, the inorganic binder including glass frit including at least one component selected from the group of lead oxide, bismuth oxide, silicon oxide, zinc oxide, and aluminum oxide.

8. The etching paste as claimed in claim 1, wherein the etching paste is substantially free from a fluorine or phosphorus compound.

9. A method of forming a selective emitter of a solar cell, the method comprising:
depositing the etching paste as claimed in claim 1 on a silicon wafer having a thin film formed thereon; and
firing the silicon wafer with the etching paste deposited thereon to simultaneously etch the thin film and dope the dopant into the silicon wafer to form a doping region.

10. The method as claimed in claim 9, wherein the silicon wafer is not subjected to pretreatment of texturing or doping.

11. The method as claimed in claim 9, wherein the firing is performed at about 800 to about 1,000° C. for about 5 to about 120 minutes.

12. The method as claimed in claim 9, further comprising depositing an electrode paste on the doping region to form an electrode.

13. The method as claimed in claim 9, wherein the thin film includes a silicon oxide film, a silicon nitride film, a metal oxide film, or a non-crystalline silicon film.

14. The method as claimed in claim 9, wherein the etching paste includes:
about 0.1 to about 98 wt % of the dopant;
about 0.1 to about 10 wt % of the binder; and
about 1.9 to about 99.8 wt % of the solvent.

15. The method as claimed in claim 9, wherein the dopant includes at least one selected from lanthanum boride (LaB₆) powder, aluminum (Al) powder, metal bismuth (Bi) powder, and bismuth oxide (Bi₂O₃) powder.

16. The method as claimed in claim 9, wherein the binder includes an organic binder, an inorganic binder, or a mixture thereof.

17. The method as claimed in claim 16, wherein the binder includes the organic binder, the organic binder including at least one selected from the group of cellulose resins, (meth)acrylic resins, and polyvinyl acetal resins.

18. The method as claimed in claim 16, wherein the binder includes the inorganic binder, the inorganic binder including glass frit including at least one component selected from the group of lead oxide, bismuth oxide, silicon oxide, zinc oxide, and aluminum oxide.

19. The method as claimed in claim 9, wherein the etching paste is substantially free from a fluorine or phosphorus compound.
